(19) United States
(12) Patent Application Publication
(10) Pub. No.: US 2009/0152101 A1
(43) Pub. Date: Jun. 18, 2009

(54) Processes for Fabrication of Gold-Aluminum Oxide and Gold-Titanium Oxide Nanocomposites for Carbon Monoxide Removal at Room Temperature

(75) Inventors: Eugene Deyneka, Apex, NC (US); Chandra K. Banerjee, Clemmons, NC (US); Jagannathan Sankar, Greensboro, NC (US)

Correspondence Address: MYERS BIGEL SIBLEY & SAJOVEC, PO BOX 37428, RALEIGH, NC, 27627, US

(73) Assignee: North Carolina Argicultural and Technical State University

(21) Appl. No.: 12/202,709

(22) Filed: Sep. 2, 2008

Related U.S. Application Data
(60) Provisional application No. 60/969,041, filed on Aug. 30, 2007.

(51) Int. Cl. C23C 14/35

(52) U.S. Cl. 204/192.15; 977/890

(57) ABSTRACT

The present invention provides methods of making nanocomposite materials for carbon monoxide removal. Methods of using the nanocomposite materials for carbon monoxide removal are also provided.

### RELATED APPLICATION INFORMATION

This application claims the priority to and the benefit of U.S. Patent Application Ser. No. 60/969,041, filed Aug. 30, 2007, the disclosure of which is incorporated by reference herein in its entirety.

### FIELD OF THE INVENTION

The present invention relates to methods of making nanocomposite materials that can be used to remove carbon monoxide from an environment containing the same. The present invention further relates to methods of removing carbon monoxide from a carbon monoxide-containing environment.

### BACKGROUND OF THE INVENTION

Carbon monoxide (CO) is an odorless, colorless gas and hence is difficult to detect. The adverse effects of the gas on health have been well documented. Because of its high affinity for hemoglobin, it may interfere with oxygen metabolism, which, in turn, is vital to numerous biological functions. CO is a major pollutant in both indoor and outdoor environments and causes more than 500 unintentional deaths per year. A major source of CO is the combustion of coal and other carbonaceous materials, such as natural gas, diesel, gasoline and other petroleum-based products. An approach that has been successfully used to reduce the amount of CO from a CO-containing environment is the use of catalysts that convert CO to CO₂. Several noble metals like palladium and platinum and their compounds have been successfully used as catalysts for this application. However, these catalysts are typically expensive, and because of their high energy of activation, they must be held at a temperature of several hundred degrees. Thus, there is a need for a commercially available catalyst that is cost effective and/or operates at or near ambient temperatures.

Recent discoveries in nanotechnology have led to the identification of gold nanoparticles as a catalyst suitable for this application. Gold nanoparticles in combination with an oxide substrate can catalyze the oxidation of CO at room temperature or even below. Since the discovery of this nanocomposite as a room temperature CO catalyst, there has been interest in its synthesis. Among the desired properties of nanocomposites for use as catalysts are shape and size of the gold particle as well as its interaction with an oxide substrate. For high efficiency catalysis, the gold nanoparticles size is generally 5 nm or less and is generally in intimate contact with the oxide substrate.

Several chemical and physical processes have been used to fabricate gold catalysts. Deposition-precipitation and co-precipitation techniques have been methods of choice. These processes produce nanoparticles having a narrow size range, and hence, have relatively desirable catalytic activity. Deposition-precipitation has also been used to produce commercial quantities of the catalysts. However, these chemical methods are cumbersome, require several process steps, and utilize large volumes of water. Moreover the nanocomposites fabricated by chemical processes are susceptible to contamination with other ions, which may have adverse effects on the catalytic properties of the nanocomposites. Also, the chemical processes are sensitive to the pH conditions. Thus, there is a need for a new process to fabricate the gold nanocomposite.

### SUMMARY OF THE INVENTION

Magnetron sputtering is commonly used to apply continuous uniform coatings on substrates. The present invention provides a novel approach to the fabrication of catalytic nanocomposite materials by a magnetron sputtering process, wherein the magnetron sputtering process promotes formation of discrete islands of a target material on a substrate surface in contrast to conventional continuous film formation. Aspects of the invention further provide a one-step magnetron sputtering process. Further aspects of the present invention include co-sputtering of the target and substrate materials.

Additional aspects of the present invention provide processes for the removal of carbon monoxide from a carbon monoxide-containing environment including introducing a catalytic nanocomposite material to said environment to catalyze the oxidation of carbon monoxide, wherein the catalytic nanocomposite material is formed by forming discrete islands of a metal or metal oxide on a substrate using a magnetron sputtering process, and wherein the catalytic nanocomposite material operates at or about room temperature.

### DETAILED DESCRIPTION

The foregoing and other aspects of the present invention will now be described in more detail with respect to other embodiments described herein. It should be appreciated that the invention can be embodied in different forms and should not be construed as limited to the embodiments set forth herein. Rather, these embodiments are provided so that this disclosure will be thorough and complete, and will fully convey the scope of the invention to those skilled in the art.

The terminology used in the description of the invention herein is for the purpose of describing particular embodiments only and is not intended to be limiting of the invention. As used in the description of the embodiments of the invention and the appended claims, the singular forms “a,” “an” and “the” are intended to include the plural forms as well, unless the context clearly indicates otherwise. As used herein, the term “and/or” includes any and all combinations of one or more of the associated listed items.

Unless otherwise defined, all technical and scientific terms used herein have the same meaning as commonly understood by one of ordinary skill in the art to which this invention belongs.

Embodiments of the present invention include methods of making a nanocomposite material for carbon dioxide removal comprising forming discrete islands of a target metal or metal oxide on a substrate using a magnetron sputtering process. The nanocomposite material is capable of catalyzing the oxidation of carbon monoxide. A further property of the nanocomposite material includes its ability to catalyze the oxidation of carbon monoxide at room temperature. As used herein, room temperature also refers to ambient temperature, which can be in a range from about 22° C. (71.6° F.) to about 28° C. (82.4° F.).

The target metals that may used in the methods described herein include gold, copper and zinc. In some embodiments, the metal is gold. Target metal oxides that may used in the methods described herein include, but are not limited to, gold oxide, copper oxide and zinc oxide. In some embodiments, the metal oxide is gold oxide. Substrate materials that may be used in the methods described herein include, but are not limited to, aluminum, titanium, silicon and magnesium. In some embodiments, the substrate material is aluminum or titanium. The substrate material may also be a metal oxide. In some embodiments, the substrate material is aluminum oxide, titanium dioxide or silicon oxide.

In embodiments disclosed herein, sputtering process parameters can be controlled in such a way as to promote formation of discrete islands of the target on the substrate surface as opposed to continuous film formation. In some embodiments, the magnetron sputtering instrument is utilized to fabricate nanoparticles of less than 5 μm in diameter in the form of islands deposited on substrates in the form of monoliths, or granules of about 600 to 800 μm in diameter. In particular embodiments, the magnetron sputtering instrument is utilized to fabricate gold nanoparticles of less than 5 μm in diameter in the form of islands deposited on aluminum oxide or titanium oxide substrates in the form of monoliths, or granules of about 600 to 800 μm in diameter.

In some embodiments of the present invention, the methods disclosed herein use direct current (dc) and radio-frequency (rf) magnetron sputtering for the deposition of nanoparticles directly on substrate granules of defined size distribution. The sputtering gas employed in the processes described herein can be any sputtering gas as known to those skilled in the art. In some embodiments, the sputtering gas is an inert gas. In some embodiments, the sputtering gas is argon.

The size of the target particles and their adhesion to the substrate can be controlled by adjusting substrate pre-sputtering conditions, the sputtering base pressure, sputtering gas content and pressure, dc and rf input power, substrate temperature, substrate bias, substrate to target distance and angle, substrate movement, sputtering time, in-situ annealing environment, time and/or temperature.

In a particular embodiment of the present invention, gold nanoparticles having a characteristic diameter in a range of about 4 to 5 μm are deposited on an aluminum oxide layer on silicon wafers using a multi-target sputtering system (ATC-1800F, AJA International, Inc., N. Scituate, Mass.). The following sputtering parameters are used in this process: base pressure of about 3×10⁻⁷ Torr; sputtering pressure of about 250 mTorr; an argon sputtering gas; rf power of about 100 W; substrate temperature of about 160° C.; bias voltage of about 145V and deposition time of about 5 minutes.

According to embodiments of the present invention, during the sputtering process, substrate granules are held in a fluidized state (for example, by vibration or agitation or by some other physical means) to promote uniform distribution of the deposited target material on the substrate.

According to further embodiments, following sputtering, the coated granules may be exposed to thermal treatment. The thermal treatment may increase interaction between the target material and the substrate material.

According to additional embodiments of the present invention, the target material and substrate material are co-sputtered to provide the nanocomposite materials.

As described herein, embodiments of the present invention provide methods wherein a magnetron sputtering process is used to form a nanocomposite material by promoting the formation of discrete islands of metal or metal oxides that are uniformly distributed on a substrate surface to provide a nanocomposite material capable of CO removal at room temperatures The nanocomposite material formed as described herein can then be utilized in a CO-containing environment to catalyze the oxidation of CO to CO₂ at room temperature.

The foregoing is illustrative of the present invention, and is not to be construed as limiting thereof. The invention is defined by the following claims, with equivalents of the claims to be included therein.

That which is claimed is:

1. A method of making a nanocomposite material for carbon dioxide removal comprising forming discrete islands of a metal or metal oxide on a substrate using a magnetron sputtering process.

2. The method of claim 1, wherein the metal is selected from the group consisting of gold, copper and zinc.

3. The method of claim 1, wherein the metal is gold.

4. The method of claim 1, wherein the metal oxide is selected from the group consisting of gold oxide, copper oxide and zinc oxide.

5. The method of claim 1, wherein the substrate is a metal selected from the group consisting of aluminum, titanium, silicon and magnesium.

6. The method of claim 5, wherein the substrate is an oxide of the metal.

7. The method of claim 1, wherein the substrate is aluminum oxide or titanium dioxide.

8. The method of claim 1, wherein nanoparticles of less than about 5 nm in diameter of the metal or metal oxide are formed to provide the discrete islands on the substrate.

9. The method of claim 1, wherein the substrate particles are held in a fluidized state.

10. The method of claim 1 further comprising conducting a thermal treatment process after conducting the magnetron sputtering process.

11. The method of claim 1, wherein the metal or metal oxide and the substrate particles are co-sputtered.

12. A process for the oxidation of carbon monoxide in a carbon monoxide-containing environment comprising introducing a nanocomposite material to said environment, wherein the nanocomposite material is formed by forming discrete islands of a metal or metal oxide on a substrate using a magnetron sputtering process and the nanocomposite material operates at or about room temperature.

13. The process of claim 12, wherein the metal is selected from the group consisting of gold, copper and zinc.

14. The method of claim 12, wherein the metal is gold.

15. The method of claim 12, wherein the metal oxide is selected from the group consisting of gold oxide, copper oxide and zinc oxide.

16. The method of claim 12, wherein the substrate is a metal selected from the group consisting of aluminum, titanium, silicon and magnesium.

17. The method of claim 16, wherein the substrate is an oxide of the metal.

18. The method of claim 12, wherein the substrate is aluminum oxide or titanium dioxide.
